(19) United States
(12) Patent Application Publication
(10) Pub. No.: US 2026/0129896 A1
(43) Pub. Date: May 7, 2026

(54) SEMICONDUCTOR DEVICE

(71) Applicants: Kabushiki Kaisha Toshiba, Kawasaki-shi (JP); Toshiba Electronic Devices & Storage Corporation, Kawasaki-shi (JP)

(72) Inventors: Hitoshi KOBAYASHI, Yamato Kanagawa (JP); Yorito KAKIUCHI, Yokohama Kanagawa (JP); Akira YOSHIOKA, Yokohama Kanagawa (JP); Tetsuya OHNO, Yokohama Kanagawa (JP); Ken HIROSE, Yokohama Kanagawa (JP); Hideki SEKIGUCHI, Yokohama Kanagawa (JP)

(21) Appl. No.: 19/427,941

(22) Filed: Dec. 19, 2025

Related U.S. Application Data
(63) Continuation of application No. PCT/JP2024/009360, filed on Mar. 11, 2024.

(51) Int. Cl. H10D 30/47; H10D 30/01; H10D 62/10; H10D 62/60; H10D 62/824; H10D 64/00

(52) U.S. Cl. CPC H10D 30/475; H10D 62/103; H10D 62/60; H10D 62/824; H10D 64/112; H10D 30/014

(57) ABSTRACT

According to one embodiment, a semiconductor device includes a semiconductor layer, a first electrode, a second electrode, and a gate electrode. The semiconductor layer contains gallium nitride. The semiconductor layer includes a first region, a second region, a third region, and a fourth region. The third region is located between the first region and the second region in a first direction. The first direction is from the first region toward the second region. The fourth region is located between the second region and the third region. A hydrogen concentration in the fourth region is higher than a hydrogen concentration in the third region. The first electrode is provided on the first region. The second electrode is provided on the second region. The gate electrode is provided on the third region with a first insulating layer interposed.

### CROSS-REFERENCE TO RELATED APPLICATIONS

This is a continuation application of International Patent Application PCT/JP 2024/009360, filed on Mar. 11, 2024. The entire contents of which are incorporated herein by reference.

### FIELD

Embodiments described herein relate generally to a semiconductor device.

### BACKGROUND

A semiconductor device using gallium nitride is known. For this semiconductor device, a reduction in on-resistance has been demanded.

### BRIEF DESCRIPTION OF THE DRAWINGS

FIG. 1 is a cross-sectional view illustrating a semiconductor device according to an embodiment;

FIGS. 2A to 2C are cross-sectional views illustrating a method for manufacturing the semiconductor device according to the embodiment;

FIGS. 3A and 3B are cross-sectional views illustrating the method for manufacturing the semiconductor device according to the embodiment;

FIGS. 4A to 4C are cross-sectional views illustrating the method for manufacturing the semiconductor device according to the embodiment;

FIG. 5A is a cross-sectional view illustrating a semiconductor device according to a reference example, and FIG. 5B is a graph illustrating characteristics of the semiconductor device according to the reference example;

FIG. 6A is a cross-sectional view illustrating the semiconductor device according to the embodiment, and FIG. 6B is a graph showing characteristics of the semiconductor device according to the embodiment;

FIG. 7 is an enlarged cross-sectional view of a part of the semiconductor device according to the embodiment;

FIG. 8A is a cross-sectional view illustrating a semiconductor device according to a first modified example of the embodiment, and FIG. 8B is a graph illustrating characteristics of the semiconductor device according to the first modified example of the embodiment; and

FIG. 9A is a cross-sectional view illustrating a semiconductor device according to a second modified example of the embodiment, and FIG. 9B is a graph illustrating characteristics of the semiconductor device according to the second modified example of the embodiment.

### DETAILED DESCRIPTION

According to one embodiment, a semiconductor device includes a semiconductor layer, a first electrode, a second electrode, and a gate electrode. The semiconductor layer contains gallium nitride. The semiconductor layer includes a first region, a second region, a third region, and a fourth region. The third region is located between the first region and the second region in a first direction. The first direction is from the first region toward the second region. The fourth region is located between the second region and the third region. A hydrogen concentration in the fourth region is higher than a hydrogen concentration in the third region. The first electrode is provided on the first region. The second electrode is provided on the second region. The gate electrode is provided on the third region with a first insulating layer interposed.

Various embodiments will be described hereinafter with reference to the accompanying drawings.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

In the specification and drawings, components similar to those described or illustrated in a drawing thereinabove are marked with like reference numerals, and a detailed description is omitted as appropriate.

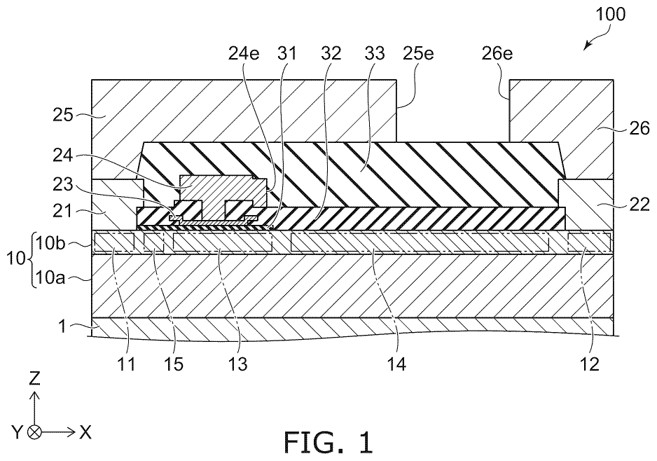

FIG. 1 is a cross-sectional view illustrating a semiconductor device according to an embodiment.

As shown in FIG. 1, a semiconductor device 100 according to the embodiment includes a semiconductor substrate 1, a semiconductor layer 10, a source electrode 21 (first electrode), a drain electrode 22 (second electrode), a gate electrode 23, a field plate electrode (FP electrode) 24, an FP electrode 25, an FP electrode 26, a first insulating layer 31, a second insulating layer 32, and a third insulating layer 33.

In the description of the embodiment, an XYZ orthogonal coordinate system is used. A direction from the semiconductor substrate 1 toward the semiconductor layer 10 is defined as a Z-direction. Two directions that are perpendicular to the Z-direction and perpendicular to each other are defined as an X-direction (first direction) and a Y-direction. For convenience of explanation, the direction from the semiconductor substrate 1 toward the semiconductor layer 10 is referred to as “upward”, and the opposite direction is referred to as “downward”. These directions are based on a relative positional relationship between the semiconductor substrate 1 and the semiconductor layer 10 and are independent of the direction of gravity.

The semiconductor layer 10 is provided on the semiconductor substrate 1. The semiconductor layer 10 contains gallium nitride. Specifically, the semiconductor layer 10 includes a first layer 10a and a second layer 10b. The first layer 10a contains Alₓ₁Ga₁₋ₓ₁N (0≤x1<1). The second layer 10b contains Alₓ₂Ga₁₋ₓ₂N (0<x2<1, x1<x2). As one example, the first layer 10a is a gallium nitride layer substantially free from Al, and the second layer 10b is an aluminum gallium nitride layer. A buffer layer (not shown) or the like may be provided between the semiconductor substrate 1 and the semiconductor layer 10.

The semiconductor layer 10 (the second layer 10b) includes a first region 11, a second region 12, a third region 13, a fourth region 14, and a fifth region 15. A direction from the first region 11 toward the second region 12 is parallel to the X-direction. The third region 13 is located between the first region 11 and the second region 12 in the X-direction. The fourth region 14 is located between the second region 12 and the third region 13 in the X-direction. The fifth region 15 is located between the first region 11 and the third region 13 in the X-direction.

The hydrogen concentration in the fourth region 14 is higher than the hydrogen concentration in the third region 13. Hydrogen concentrations in respective ones of the first region 11, the second region 12, and the fifth region 15 may be set as appropriate. For example, the hydrogen concentration in the fourth region 14 may be higher than respective hydrogen concentrations in the first region 11, the second region 12, the third region 13, and the fifth region 15.

The source electrode 21 is provided on the first region 11. The drain electrode 22 is provided on the second region 12. The source electrode 21 and the drain electrode 22 are separated from each other in the X-direction. The source electrode 21 and the drain electrode 22 are electrically connected to the semiconductor layer 10.

The gate electrode 23 is provided on the third region 13 via the first insulating layer 31. The gate electrode 23 is located between the source electrode 21 and the drain electrode 22. The distance in the X-direction between the drain electrode 22 and the gate electrode 23 is longer than the distance in the X-direction between the source electrode 21 and the gate electrode 23.

The first insulating layer 31 functions as a gate insulating layer and is in contact with the upper surface of the third region 13 and the upper surface of the fifth region 15. The second insulating layer 32 is provided on the fourth region 14, the gate electrode 23, and the first insulating layer 31. The thickness (dimension in the Z-direction) of the second insulating layer 32 is greater than the thickness of the first insulating layer 31. A part of the second insulating layer 32 is arranged alongside the first insulating layer 31 in the X-direction and is in contact with the upper surface of the fourth region 14.

The FP electrode 24 is provided on the gate electrode 23 and the second insulating layer 32. A part of the FP electrode 24 extends in the Z-direction through the second insulating layer 32 and is in contact with the gate electrode 23. Accordingly, the FP electrode 24 is electrically connected to the gate electrode 23. An end portion 24e of the FP electrode 24 in the X-direction is located on a side toward the drain electrode 22 with respect to the gate electrode 23. That is, the position of the end portion 24e in the X-direction is between the position of the drain electrode 22 in the X-direction and the position of the gate electrode 23 in the X-direction.

The third insulating layer 33 is provided on the FP electrode 24 and the second insulating layer 32. The FP electrode 25 is provided on the source electrode 21 and the third insulating layer 33 and is electrically connected to the source electrode 21. An end portion 25e of the FP electrode 25 in the X-direction is located on a side toward the drain electrode 22 with respect to the FP electrode 24. The FP electrode 26 is provided on the drain electrode 22 and the third insulating layer 33 and is electrically connected to the drain electrode 22. The FP electrode 26 is separated from the FP electrode 25 in the X-direction. An end portion 26e of the FP electrode 26 in the X-direction is located on a side toward the gate electrode 23 with respect to the drain electrode 22.

The semiconductor substrate 1 is, for example, a silicon substrate. The source electrode 21, the drain electrode 22, the gate electrode 23, and the FP electrodes 24 to 26 contain a metal material such as titanium, copper, or aluminum. The first insulating layer 31, the second insulating layer 32, and the third insulating layer 33 contain one or more insulating materials selected from the group consisting of silicon nitride, silicon oxide, and aluminum oxide.

Operation of the semiconductor device 100 will be described. A two-dimensional electron gas (2DEG) is generated at an interface between the first layer 10a and the second layer 10b. When a positive voltage is applied to the drain electrode 22 relative to the source electrode 21, electrons in the two-dimensional electron gas move from the source electrode 21 to the drain electrode 22, thereby causing a current to flow between the source electrode 21 and the drain electrode 22. When a negative voltage is applied to the gate electrode 23, electrons in a region below the gate electrode 23 are repelled due to a potential difference between the semiconductor layer 10 and the gate electrode 23, thereby causing the region to become depleted. As a result, no current flows through the semiconductor device 100.

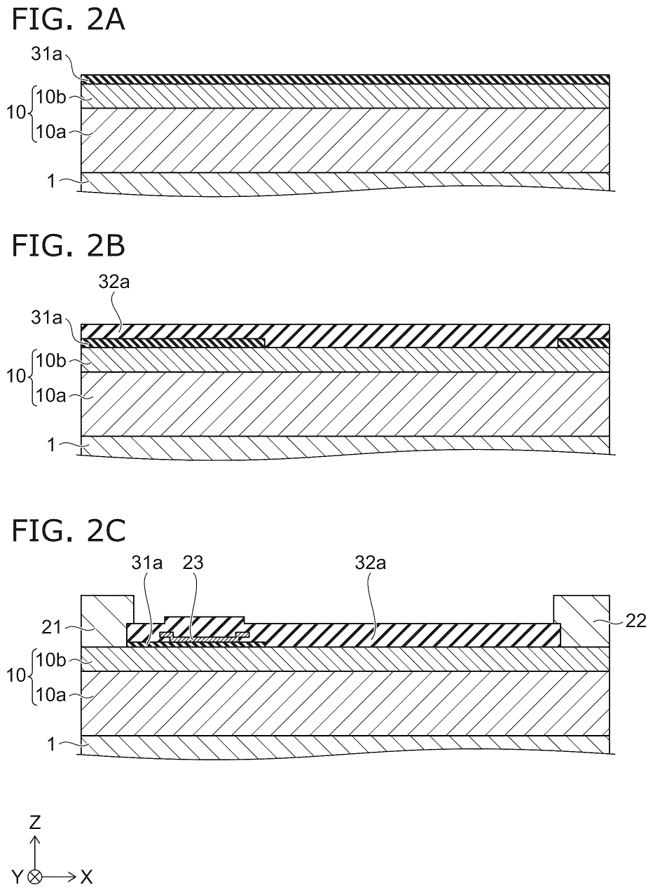

FIGS. 2A to 2C, 3A, 3B, and 4A to 4C are cross-sectional views illustrating a method for manufacturing the semiconductor device according to the embodiment.

A preferred example of a method for manufacturing the semiconductor device 100 according to the embodiment will be described. First, the semiconductor layer 10 including the first layer 10a and the second layer 10b is epitaxially grown on the semiconductor substrate 1. An insulating layer 31a is formed on the semiconductor layer 10 as shown in FIG. 2A. For example, the insulating layer 31a is formed by chemical vapor deposition (CVD). The insulating layer 31a is formed under a sufficiently reduced pressure so that incorporation of hydrogen is suppressed. It is preferable that the hydrogen concentration in the insulating layer 31a be less than 1.0×10²² cm⁻³.

A part of the insulating layer 31a is removed by etching. As a result, a part of the semiconductor layer 10 is exposed. The exposed region corresponds to the fourth region 14. An insulating layer 32a is formed on the semiconductor layer 10 and the insulating layer 31a as shown in FIG. 2B. The insulating layer 32a is formed by CVD using plasma. The pressure in a processing space when the insulating layer 32a is formed is higher than the pressure in the processing space when the insulating layer 31a is formed. Accordingly, during formation of the insulating layer 32a, a larger amount of hydrogen is incorporated into the insulating layer 32a than during formation of the insulating layer 31a. It is preferable that the hydrogen concentration in the insulating layer 32a be not less than 1.0×10²² cm⁻³.

The insulating layer 32a is in contact with a part of the semiconductor layer 10. When the insulating layer 32a is formed by CVD using plasma, the semiconductor layer 10 and the insulating layer 32a are heated during formation of the insulating layer 32a. Due to this heating, hydrogen diffuses from the insulating layer 32a into the semiconductor layer 10. As a result, the hydrogen concentration in the region in contact with the insulating layer 32a becomes higher than the hydrogen concentration in the region not in contact with the insulating layer 32a. For example, the hydrogen concentration in the region in contact with the insulating layer 32a becomes not less than 1.0×10²¹ cm⁻³. The hydrogen concentration in the region not in contact with the insulating layer 32a is less than 1.0×10²¹ cm⁻³.

By a known method, the gate electrode 23 is formed on the insulating layer 31a. The insulating layer 32a is formed on the gate electrode 23. A part of the insulating layer 31a is removed to expose a part of the semiconductor layer 10. The source electrode 21 and the drain electrode 22 are formed on the semiconductor layer 10 as shown in FIG. 2C.

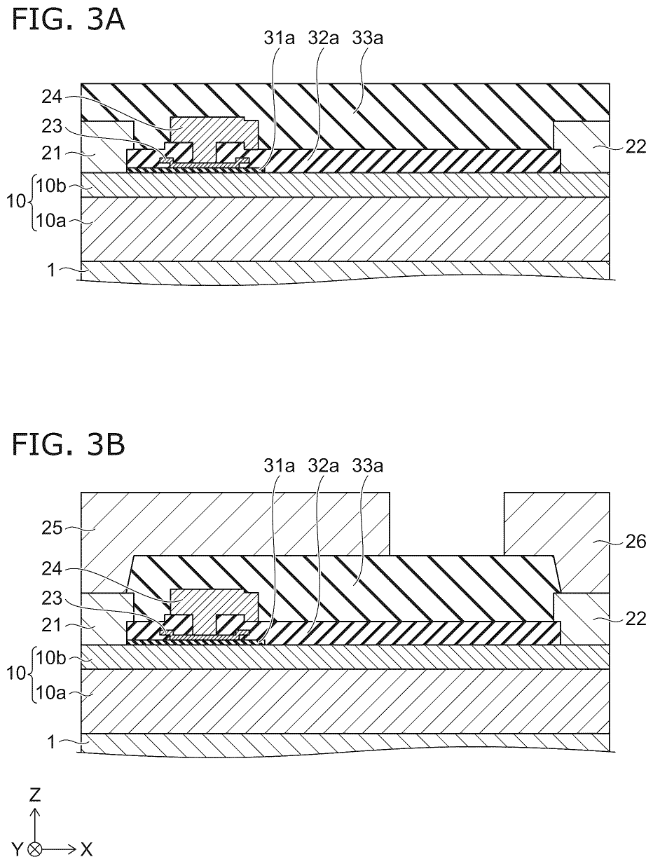

A part of the insulating layer 32a is removed, and the FP electrode 24 electrically connected to the gate electrode 23 is formed. An insulating layer 33a is formed on the FP electrode 24 and the insulating layer 32a as shown in FIG. 3A. A part of the insulating layer 33a is removed to expose the source electrode 21 and the drain electrode 22. As shown in FIG. 3B, the FP electrode 25 is formed on the source electrode 21, and the FP electrode 26 is formed on the drain electrode 22. By the above steps, the semiconductor device 100 according to the embodiment is manufactured.

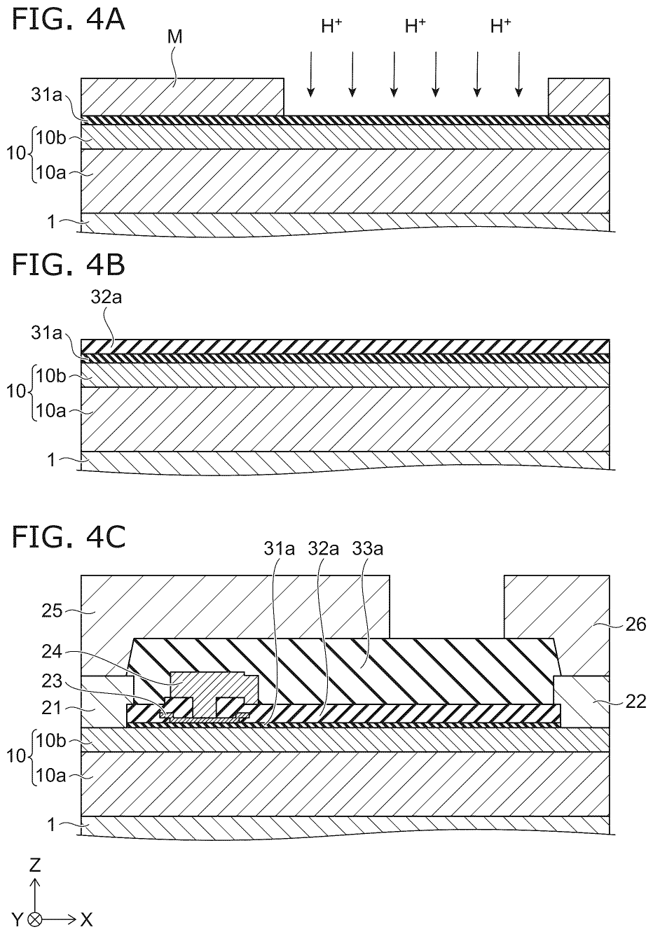

Alternatively, as shown in FIG. 4A, a mask M may be formed on the insulating layer 31a after the insulating layer 31a is formed. The mask M has an opening. The opening is located directly above a region corresponding to the fourth region 14. Hydrogen is ion-implanted into the semiconductor layer 10 through the opening. For example, the hydrogen concentration in the ion-implanted region becomes not less than 1.0×10²¹ cm⁻³. The hydrogen concentration in a region not ion-implanted is less than 1.0×10²¹ cm⁻³.

Thereafter, the insulating layer 32a is formed on the insulating layer 31a as shown in FIG. 4B. When ion implantation of hydrogen is performed, diffusion of hydrogen from the insulating layer 32a into the semiconductor layer 10 is not necessary. Therefore, the hydrogen concentration in the insulating layer 32a may be the same as the hydrogen concentration in the insulating layer 31a. The insulating layer 32a is not required to be in contact with the semiconductor layer 10. After formation of the insulating layer 32a, the source electrode 21, the drain electrode 22, the gate electrode 23, and the like are formed in the same manner as the steps shown in FIGS. 3A and 3B. As a result, the semiconductor device 100 according to the embodiment is manufactured as shown in FIG. 4C.

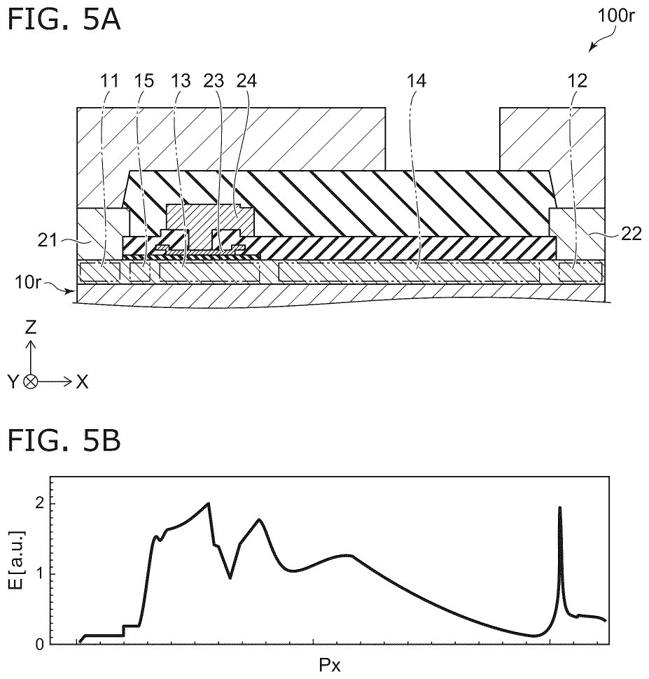

FIG. 5A is a cross-sectional view illustrating a semiconductor device according to a reference example. FIG. 5B is a graph illustrating characteristics of the semiconductor device according to the reference example.

Advantages of the embodiment according to the present invention will be described with reference to the semiconductor device according to the reference example. A semiconductor device 100r shown in FIG. 5A includes a semiconductor layer 10r. The semiconductor layer 10r, unlike the semiconductor layer 10, has a uniform hydrogen concentration. That is, in the semiconductor layer 10r, the hydrogen concentration in the fourth region 14 is the same as hydrogen concentrations in the respective ones of the first region 11, the second region 12, the third region 13, and the fifth region 15. In FIG. 5B, the horizontal axis represents a position Px in the X-direction. The vertical axis represents the electric field strength E at the interface between the first layer 10a and the second layer 10b. The electric field strength E is shown on a relative scale.

In order to reduce power consumption, it is desirable that the on-resistance of the semiconductor device 100r be low. To reduce the on-resistance, it is desirable that the carrier density in the semiconductor layer 10r be high and that the electrical resistance of the semiconductor layer 10r be low. On the other hand, when the carrier density is increased, the electric field strength at the upper surface of the semiconductor layer 10r also increases. As shown in FIG. 5B, in the semiconductor device 100r, the electric field strength increases at the upper surface of the third region 13. When the carrier density in the semiconductor layer 10r is increased, the electric field strength between the third region 13 and the gate electrode 23 becomes excessively high, and dielectric breakdown is likely to occur.

Regarding this issue, it can be seen from FIG. 5B that the electric field strength in the fourth region 14 is lower than the electric field strength in the third region 13. That is, there is a margin for increasing the electric field strength in the fourth region 14 within a range in which dielectric breakdown does not occur. Therefore, in order to reduce the on-resistance while suppressing occurrence of dielectric breakdown, it is effective to increase the carrier density in the fourth region 14 to be higher than the carrier density in the third region 13.

As a result of investigations by the inventors, it has been found that when the concentration of hydrogen contained in the semiconductor layer 10 is high, the density of the 2DEG generated between the first layer 10a and the second layer 10b also increases. Although a detailed mechanism is unclear, it is considered to be for the following reason. When the second layer 10b contains hydrogen, some hydrogen ions move to the upper surface of the second layer 10b along the electric field generated in the semiconductor layer 10. Polarity of the hydrogen ions is positive. When positive hydrogen ions accumulate at the upper surface of the second layer 10b, electrons are more likely to be generated at the boundary between the first layer 10a and the second layer 10b. Accordingly, it is considered that the density of the 2DEG generated between the first layer 10 a and the second layer 10b increases.

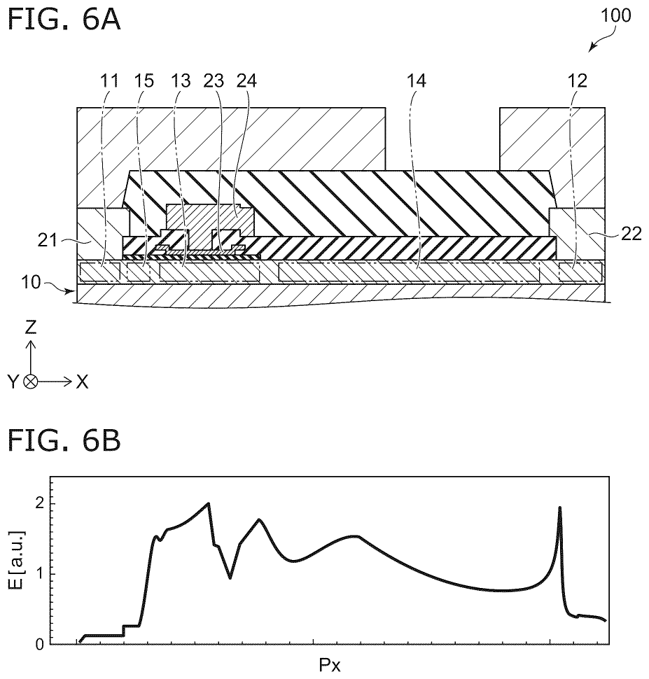

FIG. 6A is a cross-sectional view illustrating the semiconductor device according to the embodiment. FIG. 6B is a graph showing characteristics of the semiconductor device according to the embodiment. In FIG. 6B, the horizontal axis represents the position Px, and the vertical axis represents the electric field strength E. In the semiconductor device 100, the hydrogen concentration in the fourth region 14 is higher than the hydrogen concentration in the third region 13. Accordingly, the carrier density in the fourth region 14 can be increased to be higher than the carrier density in the third region 13. As a result, as compared with the semiconductor layer 10r of the semiconductor device 100r, the on-resistance in the semiconductor layer 10 between the source electrode 21 and the drain electrode 22 can be reduced. Further, even when the carrier density in the fourth region 14 is increased, as shown in FIG. 6B, an increase in the electric field strength in the third region 13 is suppressed. Therefore, occurrence of dielectric breakdown can be suppressed.

According to the embodiment, the on-resistance of the semiconductor device 100 can be reduced while suppressing occurrence of dielectric breakdown in the semiconductor device 100.

In order to reduce the electric field strength in the vicinity of the gate electrode 23, it is preferable to provide the FP electrode 24, as shown in FIG. 1. When the FP electrode 24 is provided, the electric field strength in the region directly below the end portion 24e is as high as the electric field strength in the region directly below the gate electrode 23, as shown in FIGS. 5B and 6B. Therefore, it is preferable that the FP electrode 24 be located above the third region 13. Thus, an increase in the electric field strength in the region directly below the end portion 24e can be suppressed, and occurrence of dielectric breakdown can be preferably suppressed.

Although the hydrogen concentration in the third region 13 can vary depending on manufacturing conditions of the semiconductor layer 10, from the viewpoint of reducing the electric field strength, it is preferable that the hydrogen concentration be less than 1.0×10²¹ cm⁻³. In order to sufficiently increase the carrier density, it is preferable that the hydrogen concentration in the fourth region 14 be not less than 1.0×10²¹ cm⁻³. More preferably, the hydrogen concentration in the fourth region 14 is not less than 1.0×10²² cm⁻³. The upper limit of the hydrogen concentration in the fourth region 14 is not particularly limited, but from the viewpoint of reliability tests such as a high temperature reverse bias (HTRB) test, it is preferable that the hydrogen concentration be not more than 1.0×10²³ cm⁻³.

Examples of methods for increasing the hydrogen concentration in the fourth region 14 include diffusing hydrogen from an insulating layer containing hydrogen into the semiconductor layer 10 and ion-implanting hydrogen into the semiconductor layer 10. When the two methods are compared, the method of diffusing hydrogen from the insulating layer into the semiconductor layer 10 is more preferable for suppressing damage to the crystallinity of the semiconductor layer 10. When this method is used, the hydrogen concentration in the second insulating layer 32 is higher than the hydrogen concentration in the first insulating layer 31. For example, the hydrogen concentration in the first insulating layer 31 is less than 1.0×10²² cm⁻³, and the hydrogen concentration in the second insulating layer 32 is not less than 1.0×10²² cm⁻³.

Further, when hydrogen is diffused from the second insulating layer 32 into the semiconductor layer 10, a concentration gradient of hydrogen in the Z-direction is formed in the fourth region 14. That is, the hydrogen concentration in the upper portion of the fourth region 14 becomes higher than the hydrogen concentration in the lower portion of the fourth region 14. In this state, positive hydrogen ions are more likely to accumulate at the upper surface of the second layer 10b. As a result, the density of electrons generated at the boundary between the first layer 10a and the second layer 10b can be further increased.

The hydrogen concentration in the first layer 10a may be set as appropriate, but it is preferably lower than the hydrogen concentration in the fourth region 14. For example, the hydrogen concentration in the fourth region 14 is higher than the hydrogen concentration in the region of the first layer 10a located directly below the fourth region 14. By reducing the hydrogen concentration in the first layer 10a, variations in characteristics in reliability tests such as the HTRB test can be suppressed.

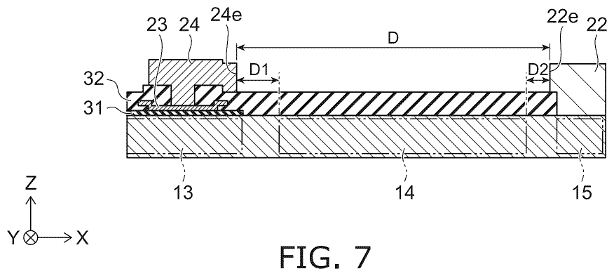

FIG. 7 is an enlarged cross-sectional view of a part of the semiconductor device according to the embodiment.

As shown in FIG. 6B, the electric field strength is high in the vicinity of the gate electrode 23 and in the vicinity of the end portion 24e. Therefore, it is preferable that the fourth region 14 be spaced apart from the gate electrode 23 and the end portion 24e. Similarly, the electric field strength is high in the vicinity of an end portion 22e of the drain electrode 22 in the X-direction. Therefore, it is preferable that the fourth region 14 be spaced apart from the end portion 22e.

For example, as shown in FIG. 7, it is preferable that the distance D1 in the X-direction between the fourth region 14 and the end portion 24 e be not less than 0.03 times and not more than 0.4 times the distance D in the X-direction between the drain electrode 22 and the end portion 24e. More preferably, the distance D1 is not less than 0.06 times and not more than 0.2 times the distance D. Note that, when the FP electrode 24 is not provided, the distance D represents the distance in the X-direction between the drain electrode 22 and the gate electrode 23, and the distance D1 represents the distance in the X-direction between the fourth region 14 and the gate electrode 23. It is preferable that the distance D2 in the X-direction between the fourth region 14 and the end portion 22 e be not less than 0.03 times and not more than 0.4 times the distance D. More preferably, the distance D2 is not less than 0.06 times and not more than 0.2 times the distance D.

Insulating materials contained in the first insulating layer 31, the second insulating layer 32, and the third insulating layer 33 may be selected as appropriate. Preferably, the first insulating layer 31 and the second insulating layer 32 contain silicon nitride, and the third insulating layer 33 contains silicon oxide. The first insulating layer 31 functions as a gate insulating layer. Therefore, the first insulating layer 31 is required to have high density, a high dielectric constant, and high insulating properties. Silicon nitride has excellent density, dielectric constant, and insulating properties as compared with oxides such as silicon oxide and aluminum oxide. In addition, compared with oxides, hydrogen is more easily incorporated into silicon nitride. Therefore, the hydrogen concentration in the second insulating layer 32 can be easily increased. On the other hand, silicon oxide exhibits smaller variations in characteristics over time than silicon nitride. When the third insulating layer 33 contains silicon oxide, variations in characteristics of the third insulating layer 33 over time can be suppressed, and long-term reliability of the semiconductor device 100 can be improved.

For example, the first to fifth regions 11 to 15 can be identified by the following method. First, the semiconductor device 100 is cut along the X-direction and the Z-direction to prepare a cross-section including the semiconductor layer 10, the source electrode 21, the drain electrode 22, and the gate electrode 23. When the cross section is observed, regions of the semiconductor layer 10 directly below the source electrode 21, the drain electrode 22, and the gate electrode 23 are identified as the first region 11, the second region 12, and the third region 13, respectively. Next, hydrogen concentrations in the second region 12, in the third region 13, and in the region between the second region 12 and the third region 13 are respectively measured. For the measurement, a scanning electron microscope (SEM)-energy-dispersive X-ray spectroscopy (EDX), a transmission electron microscope (TEM)-EDX, secondary ion mass spectrometry (SIMS), Fourier transform infrared spectroscopy (FT-IR), or the like can be used. In the region between the second region 12 and the third region 13, a portion in which the hydrogen concentration is at least twice that in the second region 12 or in the third region 13 is identified as the fourth region 14. When SEM-EDX, TEM-EDX, or SIMS is used, hydrogen concentrations in the respective regions can be measured. When FT-IR is used, hydrogen concentrations in the respective regions are estimated from amounts of hydrogen bonding in the respective regions.

### First Modified Example

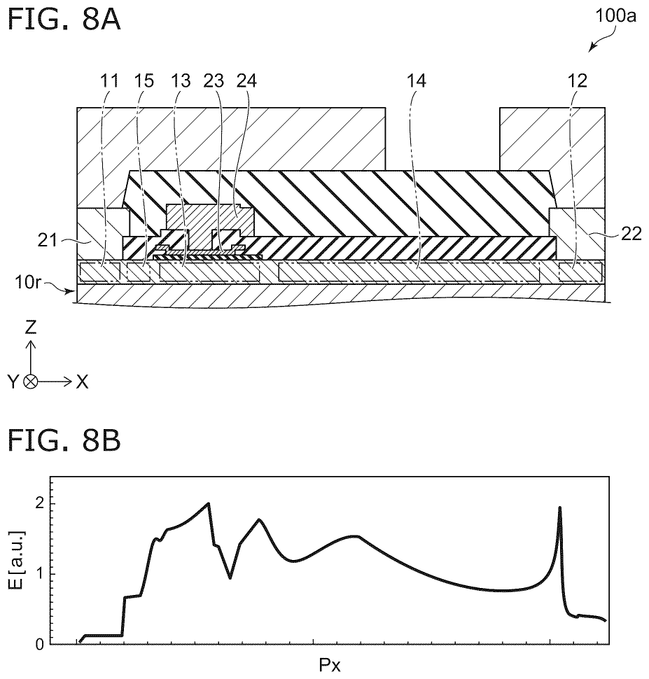

FIG. 8A is a cross-sectional view illustrating a semiconductor device according to a first modified example of the embodiment. FIG. 8B is a graph illustrating characteristics of the semiconductor device according to the first modified example of the embodiment.

In FIG. 8B, the horizontal axis represents the position Px, and the vertical axis indicates the electric field strength E. A semiconductor device 100a shown in FIG. 8A differs from the semiconductor device 100 shown in FIG. 1 in that the hydrogen concentration in the fifth region 15 is higher than the hydrogen concentration in the third region 13. It can be seen from FIG. 6B that the electric field strength in the fifth region 15 is lower than an electric field strength in the third region 13. Therefore, there is a margin for increasing the electric field strength in the fifth region 15 within a range in which dielectric breakdown does not occur.

By making the hydrogen concentration in the fifth region 15 higher than the hydrogen concentration in the third region 13, the carrier density in the fifth region 15 can be increased to be higher than the carrier density in the third region 13. Even when the carrier density in the fifth region 15 is increased, as shown in FIG. 8B, an increase in the electric field strength in the third region 13 is suppressed. Therefore, occurrence of dielectric breakdown can be suppressed.

According to the first modified example, the on-resistance of the semiconductor device 100a can be further reduced while suppressing occurrence of dielectric breakdown in the semiconductor device 100a.

### Second Modified Example

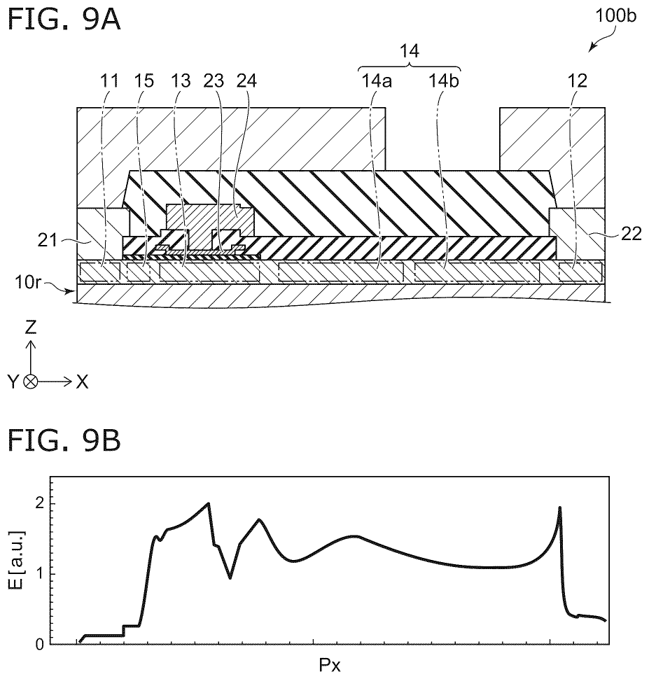

FIG. 9A is a cross-sectional view illustrating a semiconductor device according to a second modified example of the embodiment. FIG. 9B is a graph illustrating characteristics of the semiconductor device according to the second modified example of the embodiment. In FIG. 9B, the horizontal axis represents the position Px, and the vertical axis represents the electric field strength E.

A semiconductor device 100b shown in FIG. 9A differs from the semiconductor device 100 shown in FIG. 1 in that the fourth region 14 includes a first portion 14a and a second portion 14b. The second portion 14b is located between the second region 12 and the first portion 14a in the X-direction. The hydrogen concentration in the second portion 14b is higher than the hydrogen concentration in the first portion 14a. That is, the fourth region 14 has a gradient in hydrogen concentration in the X-direction.

It can be seen from FIG. 6B that, in the fourth region 14, the electric field strength in a region on the drain-electrode side is lower than the electric field strength in a region on the gate-electrode side. Therefore, even if the electric field strength in the region on the drain-electrode side in the fourth region 14 becomes higher than the electric field strength in the region on the gate-electrode side, occurrence of dielectric breakdown can be sufficiently suppressed.

According to the second modified example, the on-resistance of the semiconductor device 100b can be further reduced while suppressing occurrence of dielectric breakdown in the semiconductor device 100b.

Note that the fourth region 14 may include portions having three or more mutually different hydrogen concentrations. As a result, the on-resistance of the semiconductor device 100b can be further reduced.

Structures according to the first modified example and structures according to the second modified example can be appropriately combined. That is, the fourth region 14 may have a gradient in hydrogen concentration in the X-direction, and the hydrogen concentration in the fifth region 15 may be higher than the hydrogen concentration in the third region 13.

The embodiments according to the present invention may include the following features.

### Feature 1

A semiconductor device comprising:
a semiconductor layer containing gallium nitride and including
   a first region,
   a second region,
   a third region located between the first region and the second region in a first direction from the first region toward the second region, and
   a fourth region located between the second region and the third region, a hydrogen concentration in the fourth region being higher than a hydrogen concentration in the third region;
a first electrode provided on the first region;
a second electrode provided on the second region; and
a gate electrode provided on the third region with a first insulating layer interposed.

### Feature 2

The semiconductor device according to feature 1, further comprising a field plate electrode provided on the gate electrode and electrically connected to the gate electrode,
an end of the field plate electrode in the first direction being located on a side toward the second electrode with respect to the gate electrode, and
the field plate electrode being located above the third region.

### Feature 3

The semiconductor device according to feature 1 or 2, wherein
the hydrogen concentration in the third region is less than 1.0×10²¹ cm⁻³, and
the hydrogen concentration in the fourth region is not less than 1.0×10²¹ cm⁻³.

### Feature 4

The semiconductor device according to any one of features 1 to 3, further comprising a second insulating layer provided on the fourth region and in contact with the fourth region,
a hydrogen concentration in the second insulating layer being higher than a hydrogen concentration in the first insulating layer.

### Feature 5

The semiconductor device according to feature 4, wherein
the hydrogen concentration in the first insulating layer is less than 1.0×10²² cm⁻³, and
the hydrogen concentration in the second insulating layer is not less than 1.0×10²² cm⁻³.

### Feature 6

The semiconductor device according to any one of features 1 to 5, wherein
the hydrogen concentration in the fourth region is higher than a hydrogen concentration in the first region and is higher than a hydrogen concentration in the second region.

### Feature 7

The semiconductor device according to any one of features 1 to 6, wherein
the semiconductor layer includes a fifth region located between the first region and the third region, and
a hydrogen concentration in the fifth region is higher than the hydrogen concentration in the third region.

### Feature 8

The semiconductor device according to any one of features 1 to 7, wherein
the fourth region includes a first portion and a second portion located between the first portion and the second region, and
a hydrogen concentration in the second portion is higher than a hydrogen concentration in the first portion.

### Feature 9

The semiconductor device according to any one of features 1 to 8, wherein
the semiconductor layer includes
a first layer containing Alₓ₁Ga₁₋ₓ₁N (0≤x1<1), and
a second layer provided on the first layer and containing Alₓ₂Ga₁₋ₓ₂N (0<x2<1, x1<x2),
the second layer includes the first region, the second region, the third region, and the fourth region, and
the hydrogen concentration in the fourth region is higher than a hydrogen concentration in a region of the first layer located directly below the fourth region.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention. Moreover, above-mentioned embodiments can be combined mutually and can be carried out.

What is claimed is:

1. A semiconductor device comprising:
a semiconductor layer containing gallium nitride and including
a first region,
a second region,
a third region located between the first region and the second region in a first direction from the first region toward the second region, and
a fourth region located between the second region and the third region, a hydrogen concentration in the fourth region being higher than a hydrogen concentration in the third region;
a first electrode provided on the first region;
a second electrode provided on the second region; and
a gate electrode provided on the third region with a first insulating layer interposed.

2. The semiconductor device according to claim 1, further comprising a field plate electrode provided on the gate electrode and electrically connected to the gate electrode,
an end of the field plate electrode in the first direction being located on a side toward the second electrode with respect to the gate electrode, and
the field plate electrode being located above the third region.

3. The semiconductor device according to claim 1, wherein
the hydrogen concentration in the third region is less than 1.0×10²¹ cm⁻³, and
the hydrogen concentration in the fourth region is not less than 1.0×10²¹ cm⁻³.

4. The semiconductor device according to claim 1, further comprising a second insulating layer provided on the fourth region and in contact with the fourth region,
a hydrogen concentration in the second insulating layer being higher than a hydrogen concentration in the first insulating layer.

5. The semiconductor device according to claim 4, wherein
the hydrogen concentration in the first insulating layer is less than 1.0×10²² cm⁻³, and
the hydrogen concentration in the second insulating layer is not less than 1.0×10²² cm⁻³.

6. The semiconductor device according to claim 1, wherein
the hydrogen concentration in the fourth region is higher than a hydrogen concentration in the first region and is higher than a hydrogen concentration in the second region.

7. The semiconductor device according to claim 1, wherein
the semiconductor layer includes a fifth region located between the first region and the third region, and
a hydrogen concentration in the fifth region is higher than the hydrogen concentration in the third region.

8. The semiconductor device according to claim 1, wherein
the fourth region includes a first portion and a second portion located between the first portion and the second region, and
a hydrogen concentration in the second portion is higher than a hydrogen concentration in the first portion.

9. The semiconductor device according to claim 1, wherein
the semiconductor layer includes
a first layer containing Alₓ₁Ga₁₋ₓ₁N (0≤x1<1), and
a second layer provided on the first layer and containing Alₓ₂Ga₁₋ₓ₂N (0<x2<1, x1<x2),
the second layer includes the first region, the second region, the third region, and the fourth region, and
the hydrogen concentration in the fourth region is higher than a hydrogen concentration in a region of the first layer located directly below the fourth region.
